(19) United States
(12) Patent Application Publication
(10) Pub. No.: US 2026/0047390 A1
(43) Pub. Date: Feb. 12, 2026

(54) ERROR-CORRECTABLE PLANAR STRETCHING EXPANSION DEVICE AND METHOD FOR MINI-LED CHIPS

(71) Applicant: Guangdong University of Technology, Guangzhou (CN)

(72) Inventors: Yun CHEN, Guangzhou (CN); Zilin HE, Guangzhou (CN); Li MA, Guangzhou (CN); Xiangyuan LUO, Guangzhou (CN); Maoxiang HOU, Guangzhou (CN); Xin CHEN, Guangzhou (CN)

(21) Appl. No.: 19/366,353

(22) Filed: Oct. 22, 2025

(30) Foreign Application Priority Data
Nov. 5, 2024 (CN) 202411568774.4

(51) Int. Cl. H01L 21/68; B29C 55/14; B29L 31/34

(52) U.S. Cl. CPC H01L 21/681; B29C 55/14; B29L 2031/3406

(57) ABSTRACT

An error-correctable planar stretching expansion device for chips includes a first film expansion mechanism, a second film expansion mechanism, a film pressing frame, a scanning camera, and an error correction mechanism. The error correction mechanism includes a correction disk, ejector pins, and a drive mechanism. The first film expansion mechanism and the second film expansion mechanism are employed to stretch a blue film globally. The scanning camera detects positions of chips on the blue film. The correction disk locally secures regions of the blue film where the chips are non-deviated by means of suction through holes. The ejector pins lift regions of the blue film where the chips are deviated and unsecured, thereby performing localized stretching of the blue film, thereby correcting the positions of the chips on the blue film and enabling precise adjustment of chip alignment.

### CROSS-REFERENCE TO RELATED APPLICATIONS

This application claims the benefit of priority from Chinese Patent Application No. 202411568774.4, filed on Nov. 5, 2024. The content of the aforementioned application, including any intervening amendments made thereto, is incorporated herein by reference in its entirety.

### TECHNICAL FIELD

This application relates to Miniature Light-Emitting Diode (Mini-LED) chip manufacturing, and more particularly to an error-correctable planar stretching expansion device and method for Mini-LED chips.

### BACKGROUND

In semiconductor chip manufacturing, after chips are mass-produced on a wafer, they remain integrated as a whole. Only after dicing and separation, they form the individual chips commonly seen, with the spacing between chips corresponding to the spacing of the cutting lines. For Mini-LED chips measuring around 100 micrometers, achieving chip transfer and packaging at such minute spacings is challenging. Therefore, a film expansion process is required to widen the spacing between chips.

The traditional method for Mini-LED chip expansion using a blue film involves: placing the blue film in the center of a circular ring and securing it, and using a cylindrical rod to push up the blue film from the center of the circular ring, thereby stretching the entire blue film uniformly to increase the distance between the chips on the film.

However, the stretching deformation of the blue film is easily affected by factors such as temperature, strain, and stretching speed, making it difficult for chips to expand uniformly from the center. In practice, the chips in the central area often undergo over-expansion, while those in the four corners suffer from insufficient expansion. This method obviously fails to meet the requirements for precise horizontal and vertical alignment of Mini-LED chips. Furthermore, once errors occur after expansion, they cannot be corrected, significantly impacting the accuracy of subsequent chip transfer processes.

### SUMMARY

In view of the deficiencies in the prior art, this application provides an error-correctable planar stretching expansion device and method for Mini-LED chips. The device and method perform film expansion in two perpendicular directions along rows and columns of the chips, respectively, and allow for subsequent correction in error regions after expansion, thereby improving the alignment accuracy of the chips after the expansion process.

Technical solutions of the present disclosure are described as follows.

In a first aspect, this application provides an error-correctable planar stretching expansion device for chips, comprising:
a first film expansion mechanism;
a second film expansion mechanism;
a film pressing frame;
a scanning camera; and
an error correction mechanism;
wherein an expansion direction of the first film expansion mechanism is perpendicular to an expansion direction of the second film expansion mechanism;
the film pressing frame is configured to secure a blue film carrying the chips;
the error correction mechanism is configured to perform a localized expansion of the blue film;
the scanning camera is configured to detect positions of the chips on the blue film;
the error correction mechanism comprises a correction disk, a plurality of ejector pins, and a drive mechanism;
the correction disk is provided with a plurality of suction through holes and a plurality of correction through holes; the plurality of suction through holes are uniformly distributed in the correction disk; the plurality of suction through holes are externally connected to an air extraction mechanism; the plurality of suction through holes are configured to absorb and fix the blue film to an upper surface of the correction disk under an action of the air extraction mechanism; and the plurality of correction through holes are uniformly distributed between the plurality of suction through holes; and
the plurality of ejector pins are movably arranged in the plurality of correction through holes in a vertical direction, with one ejector pin corresponding to one correction through hole; vertical movements of the plurality of ejector pins are independent of each other; driven by the drive mechanism, at least one ejector pin moves upward to protrude the upper surface of the correction disk; and the at least one ejector pin protruding upwardly is configured to locally expand the blue film.

In an embodiment, each suction through hole is provided with a porous ceramic which flushes with the upper surface of the correction disk; the plurality of suction through holes are externally connected to the air extraction mechanism via a flexible tube; and the air extraction mechanism is a negative pressure pump; and
each ejector pin is arranged at an end of a corresponding correction through hole proximate to the upper surface of the correction disk; the each ejector pin has a cylindrical structure with a hemispherical upper end; an outer wall of the each ejector pin is sealed against an inner wall of the corresponding correction through hole; when not moving upward, an upper end of the each ejector pin does not protrude beyond the upper surface of the correction disk; and an other end of the corresponding correction through hole is connected to an air tube which is connected to the drive mechanism, wherein the drive mechanism is an external air pressure adjustment system.

In an embodiment, the each suction through hole is a cylindrical through hole with a diameter of 1 mm, and each correction through hole is a cylindrical through hole with a diameter of 1.5 mm.

In an embodiment, the error-correctable planar stretching expansion device further comprises a rotation driver configured to drive the correction disk to rotate in a horizontal direction.

In an embodiment, the film pressing frame comprises a first film pressing frame and a second film pressing frame; the first film pressing frame and the second film pressing frame are vertically stacked; and the first film pressing frame is engageable with the second film pressing frame for clamping and fixing a stretched blue film; and
a height of the second film pressing frame gradually decreases from an inner frame edge of the second film pressing frame to an outer frame edge of the second film pressing frame, forming an outward and downward inclined surface frame on an upper surface of the second film pressing frame; the inner frame edge of the second film pressing frame is provided with a protruding platform, which is flushed with the upper surface of the correction disk; and the film pressing frame is square, and a side length of the film pressing frame is less than a length L2 of the second film expansion mechanism.

In an embodiment, the error-correctable planar stretching expansion device further comprises a plurality of pressing column heads;
each pressing column head is provided with a through hole; a pushing block is disposed within the through hole and sealed against an inner wall of the through hole; a side of the through hole is connected to a third air tube, and the third air tube is externally connected to a first air pump; a side of the pushing block away from the third air tube is provided with a locking arrow, which is configured to lock the first film pressing frame and the second film pressing frame; the first film pressing frame is provided with a plurality of first locking through holes; the second film pressing frame is provided with a plurality of second locking through holes; and the plurality of first locking through holes and the plurality of second locking through holes are matched with corresponding through holes, respectively; and
under an action of the first air pump, the pushing block drives the locking arrow to move downward sequentially through each first locking through hole and each second locking through hole.

In an embodiment, the first film expansion mechanism comprises a first roller assembly and a first pressing block assembly; the first roller assembly and the first pressing block assembly are arranged oppositely and parallel to each other on both sides of the error correction mechanism in a first direction; the first roller assembly is configured to stretch a blue film in a second direction; and the first pressing block assembly is configured to secure the blue film in the second direction;
the second film expansion mechanism comprises a second roller assembly and a second pressing block assembly; the second roller assembly and the second pressing block assembly are arranged oppositely and parallel to each other on both sides of the error correction mechanism in the second direction; the second roller assembly is configured to stretch a blue film in the first direction; and the second pressing block assembly is configured to secure the blue film in the first direction;
the first direction is perpendicular to the second direction; the second roller assembly and the second pressing block assembly have a same length; the second roller assembly and the second pressing block assembly are disposed between the first roller assembly and the first pressing block assembly; and the second roller assembly is spaced apart from the first roller assembly and the first pressing block assembly;
the first roller assembly comprises a first upper roller and a first lower roller; the first upper roller and the first lower roller are directly opposite each other; and the first upper roller and the first lower roller are respectively disposed on two sides of the blue film in a thickness direction thereof;
the first pressing block assembly comprises a first upper pressing block and a first lower pressing block; the first upper pressing block and the first lower pressing block are directly opposite each other; and the first upper pressing block and the first lower pressing block are respectively disposed on the two sides of the blue film in the thickness direction thereof;
the second roller assembly comprises a second upper roller and a second lower roller; the second upper roller and the second lower roller are directly opposite each other; and the second upper roller and the second lower roller are respectively disposed on the two sides of the blue film in the thickness direction thereof; and
the second pressing block assembly comprises a second upper pressing block and a second lower pressing block; the second upper pressing block and the second lower pressing block are directly opposite each other; and the second upper pressing block and the second lower pressing block are respectively disposed on the two sides of the blue film in the thickness direction thereof.

In an embodiment, a first distance adjustment device is provided between the first upper roller and the first lower roller and configured to adjust a distance between the first upper roller and the first lower roller; and the distance between the first upper roller and the first lower roller is adjustable within a range of 0 to 10 mm;
a second distance adjustment device is provided between the second upper roller and the second lower roller and configured to adjust a distance between the second upper roller and the second lower roller; and the distance between the second upper roller and the second lower roller is adjustable within a range of 0 to 10 mm;
the first upper roller, the first lower roller, the second upper roller, and the second lower roller are each provided with a knurling having a module of 0.2 mm;
a third distance adjustment device is provided between the first upper pressing block and the first lower pressing block and configured to adjust a distance between the first upper pressing block and the first lower pressing block; and the distance between the first upper pressing block and the first lower pressing block is adjustable within a range of 0 to 10 mm;
a fourth distance adjustment device is provided between the second upper pressing block and the second lower pressing block and configured to adjust a distance between the second upper pressing block and the second lower pressing block; and the distance between the second upper pressing block and the second lower pressing block is adjustable within a range of 0 to 10 mm;
a length of the first film expansion mechanism is L1; a length of the second film expansion mechanism is L2; a side length of a maximum allowable square area of the blue film after expansion is L3, wherein L3<L2<L1; and a gap between the first film expansion mechanism and the second film expansion mechanism along a length direction of the second film expansion mechanism is d; and
L3 is less than 80 mm; L2 is 20 mm longer than a side length of the film pressing frame; L1 is greater than a side length of the blue film before expansion; and d is greater than 30 mm.

In a second aspect, this application provides an error-correctable planar stretching expansion method by the error-correctable planar stretching expansion device above, comprising:
(A) placing the blue film carrying the chips onto the correction disk, and observing a spacing between the chips on the blue film in real time by the scanning camera;
(B) performing a first bidirectional film expansion through steps of:
stretching, by the first film expansion mechanism, the blue film until a spacing between two adjacent chips along the second direction reaches 96% of a set spacing; and
stretching, by the second film expansion mechanism, the blue film until a spacing between two adjacent chips along the first direction reaches 96% of the set spacing, wherein the set spacing is a required spacing between adjacent chips for subsequent processing;
(C) performing error identification through steps of:
acquiring positions of the chips via the scanning camera;
determining whether a chip spacing in certain regions is below 95% of the set spacing:
if a chip spacing in a region is greater than or equal to 95% of the set spacing, marking the region as an adjusted region; and
if the chip spacing in a region is less than 95% of the set spacing, marking the region as an error region; selecting one error region and determining whether the one error region is a convex polygon: if yes, proceeding to a step (D); if no, the one error region is a concave polygon, dividing the concave polygon into a plurality of convex polygons and proceeding to the step (D); if the one error region is a smallest adjustable unit and cannot be divided, proceeding directly to the step (D);
(D) performing error correction through steps of:
controlling an ejector pin on the correction disk corresponding to the error region to extend upward, thereby lifting and stretching the blue film in the error region;
(E) performing error elimination verification through steps of:
re-identifying a corrected error region by the scanning camera;
if a chip spacing within the corrected error region still fails to all reach 95% of the set spacing, and the corrected error region is not the smallest adjustable unit, returning to the step (C) for re-identification and division; and

if the corrected error region is within the minimum adjustable unit, returning to the step (D) for repeat adjustment; accumulating a number of adjustments for the corrected error region, when the number of adjustments exceeds a preset maximum number of adjustments, abandoning adjustment of the corrected error region and simultaneously marking the corrected error region as an adjusted region; until all regions are marked as adjusted regions, proceeding to a step (F);
(F) performing a second bidirectional film expansion through steps of:
stretching, by the first film expansion mechanism, the blue film after the error elimination verification, wherein the scanning camera observes chip spacings in the second direction in real time, when an average chip spacing equals to the set spacing, and stopping stretching steps; and
stretching, by the second film expansion mechanism, the blue film; wherein the scanning camera observes chip spacings in the first direction in real time, when an average chip spacing in the first direction equals the set spacing, and completing stretching.

In a third aspect, this application provides a Mini-LED chip film expansion apparatus, comprising the error-correctable planar stretching expansion device above.

Compared to the prior art, the present disclosure has the following beneficial effects.

The first film expansion mechanism and the second film expansion mechanism are employed to stretch the blue film globally. Subsequently, the scanning camera detects the positions of the chips on the blue film. Then, the correction disk locally secures the regions of the blue film where the positions of the chips are non-deviated by means of suction through holes. Next, the ejector pins lift the regions of the blue film where the positions of the chips are deviated and unsecured, thereby performing localized stretching of the blue film. This process corrects the positions of the chips on the blue film, enabling precise placement adjustment of the chips. This process addresses the limitations of conventional film expansion devices, which cannot arbitrarily adjust the localized stretching amount of the blue film or correct local positional deviations of the chips.

By rotating the correction disk, the alignment direction of the chips is adjusted to be parallel to the stretching direction of the film expansion device, thereby resolving the difficulty in calculating position adjustments when the chip arrangement direction differs from the stretching direction.

Sufficient buffer zones are maintained at the edges and central region of the blue film to ensure uniform stretching in the central region. This addresses the issue of irregular deformation in the film center caused by insufficient buffer zones.

By initially stretching the blue film to 96% of the target maximum spacing, margin is provided for local error adjustment. This prevents over-expansion of the blue film while avoiding the need for excessive stretching in subsequent steps, which would otherwise lead to increased new errors.

By dividing error regions and adjusting chip spacing region by region, 99% of chip spacings achieve 95-96% of the preset maximum spacing during the error correction phase, thereby minimizing the final average chip offset.

### BRIEF DESCRIPTION OF THE DRAWINGS

FIG. 1 schematically shows a structure of an error-correctable planar stretching expansion device for chips according to one embodiment of the present disclosure;

FIG. 2 schematically shows the structure of the error-correctable planar stretching expansion device for chips from another perspective;

FIG. 3 schematically shows a working process of the error-correctable planar stretching expansion device;

FIG. 4 is a partially enlarged view of a film pressing frame with a locking arrow according to one embodiment of the present disclosure;

FIG. 5 is a perspective view of a first film pressing frame according to one embodiment of the present disclosure;

FIG. 6 is a perspective view of a second film pressing frame according to one embodiment of the present disclosure;

FIG. 7 is a sectional view of the second film pressing frame; and

FIG. 8 is a partially enlarged view of section A in FIG. 7.

In the drawings: first roller assembly 11; first pressing block assembly 12; second roller assembly 21; second pressing block assembly 22; second upper roller 21A; second lower roller 21B; second upper pressing block 22A; second lower pressing block 22B; second distance adjustment device 23; fourth distance adjustment device 24; film pressing frame 3; first film pressing frame 31; second film pressing frame 32; locking through hole 33; first locking through hole 33A; second locking through hole 33B; protruding platform 34; scanning camera 4; error correction mechanism 5; correction disk 51; ejector pin 52; suction through hole 53; correction through hole 54; porous ceramic 55; drive mechanism 56; air extraction mechanism 57; pressing column head 6; through hole 61; pushing block 62; locking arrow 7; chip 8; blue film 9; and
L1 represents a length of the first film expansion mechanism; L2 represents a length of the second film expansion mechanism; L3 represents a side length of the maximum allowable square area of the blue film after expansion; and d represents a gap between the first film expansion mechanism and the second film expansion mechanism along a length direction of the second film expansion mechanism.

### DETAILED DESCRIPTION OF EMBODIMENTS

The disclosure will be further described in detail below with reference to the embodiments and accompanying drawings. The same or similar reference numerals throughout refer to the same or similar elements or elements having the same or similar functions. It should be understood that the embodiments described below are exemplary and intended to explain the present disclosure and not intended to limit the disclosure.

As used herein, it should be noted that the orientation or positional relationships indicated by terms such as “longitudinal”, “transverse”, “upper”, “lower”, “front”, “rear”, “left”, “right”, “vertical”, “horizontal”, “top”, “bottom”, “inner”, and “outer”, are based on the orientation or positional relationships shown in the drawings. These terms are used only for the convenience of describing and simplifying the description, rather than indicating or implying that the indicated device or element must have a specific orientation, be constructed or operated in a specific orientation. Therefore, these terms should not be understood as a limitation of the present disclosure. Furthermore, the terms “first” and “second” are merely descriptive and cannot be understood as indicating or implying relative importance or as implying the number of technical features indicated. Thus, features defined by “first” or “second” may explicitly or implicitly include at least one such feature.

In the description of the present disclosure, the term “multiple” means at least two, such as two, three, etc., unless otherwise explicitly and specifically defined.

As used herein, unless otherwise expressly specified and defined, the terms, such as “mount”, “connect”, “couple”, and “fix” should be understood in a broad sense, for example, it may be fixed connection, detachable connection, or integral connection; it may be mechanical connection, or electrical connection; it may be direct connection or indirect connection through an intermediate medium; and it may be internal communication or interactive relationship between two members. For those skilled in the art, the specific meanings of the above terms can be understood according to specific situations.

The present disclosure will be described in detail with reference to the accompanying drawings and embodiments.

An error-correctable planar stretching expansion device for chips includes a first film expansion mechanism, a second film expansion mechanism, a film pressing frame 3, a scanning camera 4, and an error correction mechanism 5.

Expansion directions of the first film expansion mechanism and the second film expansion mechanism are mutually perpendicular. The film pressing frame 3 is used to secure the blue film carrying chips 8. The error correction mechanism 5 is used for performing localized expansion of the blue film 9. The scanning camera 4 is used to detect the positions of the chips 8 on the blue film 9.

The error correction mechanism 5 includes a correction disk 51, a plurality of ejector pins 52, and a drive mechanism 56. The correction disk 51 is provided with a plurality of suction through holes 53 and a plurality of correction through holes 54. The suction through holes 53 are evenly distributed in the correction disk 51. Each suction through hole 53 is externally connected to an air extraction mechanism 57. Under the action of the air extraction mechanism 57, the blue film 9 is absorbed and secured to the upper surface of the correction disk 51 by the suction through holes 53. The correction through holes 54 are uniformly distributed between the suction through holes 53. The ejector pins 52 are movably disposed in the correction through holes 54, with one ejector pin corresponding to each correction through hole. The vertical movements of the plurality of ejector pins 52 are independent of each other. Driven by the drive mechanism 56, at least one ejector pin 52 moves upward to protrude the upper surface of the correction disk 51. The ejector pin 52 protruding upwardly serves to locally expand the blue film 9.

The target for chip transfer is to transfer the chips onto the two-dimensional array on the substrate. Chip transfer requires that each chip be aligned with the two-dimensional array on the substrate. During the transfer process, the bonding head, the chips 8, and the array on the substrate must be precisely aligned one-to-one. If the positional accuracy of chips 8 on the blue film 9 is sufficiently high, the error compensation movement of the blue film 9 can be reduced, thereby improving the final transfer accuracy.

With this structure, the first film expansion mechanism and the second film expansion mechanism are used to stretch the blue film 9 globally. Subsequently, the scanning camera 4 detects the positions of chips 8 on the blue film 9. Then, the correction disk 51 locally secures the regions of the blue film 9 where the positions of the chips 8 are non-deviated by means of suction through holes 53. Next, the ejector pins 52 lift the regions of the blue film 9 where the positions of the chips 8 are deviated and unsecured, thereby performing localized stretching of the blue film 9. This process corrects the positions of the chips 8 on the blue film 9, enabling precise placement adjustment of the chips 8. This process addresses the limitations of conventional film expansion devices, which cannot arbitrarily adjust the localized stretching amount of the blue film 9 or correct local positional deviations of the chips 8.

The following compares the average transfer error of chips 8 for poorly-expanded and well-expanded blue films using the same die bonder.

| | X-direction | Y-direction |
|---|---|---|
| | Offset (μm) | Offset (μm) |
| Conventional expansion | 4.1 | 6.7 |
| Error-correctable expansion | 0.8 | 1.3 |
| (This disclosure) | | |

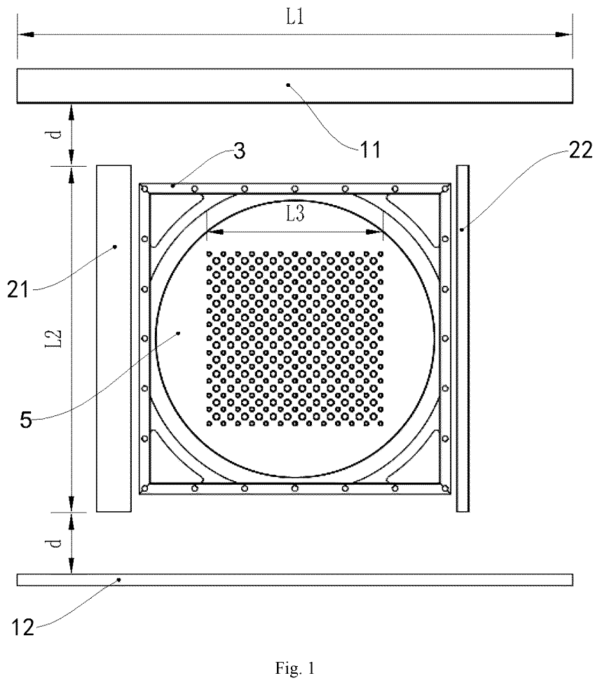

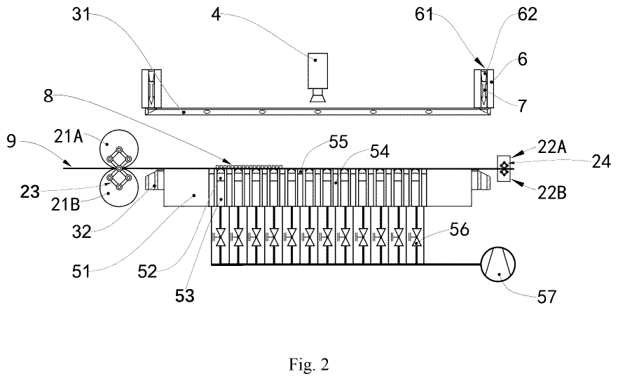

As shown in FIGS. 1 and 2, the correction disk 51 is a circular disk. The suction through holes 53 are distributed in a two-dimensional array on the correction disk 51. The suction through holes 53 are connected to an external vacuum pump via air tubes. The vacuum pump provides negative pressure to secure the blue film 9 in place through the suction through holes 53. The correction through holes 54 are positioned at the center of the rectangle formed by four adjacent suction through holes 53. The correction through holes 54 are connected to an external air pressure adjustment system via an air tube. The air pressure adjustment system provides positive or negative pressure to drive the ejector pins 52 within the correction through holes 54 to move along its longitudinal direction.

In this embodiment, a porous ceramic 55 is disposed inside each suction through hole 53. The porous ceramic 55 flushes with the upper surface of the correction disk 51. The suction through hole 53 is connected to an external air extraction mechanism 57 via a flexible tube, and the air extraction mechanism 57 is a negative pressure pump.

Each ejector pin 52 is disposed at the end of the correction through hole 54 near the upper surface of the correction disk 51. The ejector pin 52 has a cylindrical structure with a hemispherical upper end. The outer wall of the ejector pin 52 is sealed against the inner wall of the correction through hole 54. When not moving upward, the upper end of the ejector pin 52 does not protrude beyond the upper surface of the correction disk 51. The other end of the correction through hole 54 is connected to an air tube, which is connected to the drive mechanism 56. The drive mechanism 56 is an external air pressure adjustment system.

This structure employs the porous ceramic 55 to prevent deformation of the blue film 9 during adsorption, thereby avoiding any adverse effect on the position of the chip 8.

The air pressure adjustment system is used to control the extension of the ejector pin 52 within the correction through hole 54 to lift the blue film 9. By regulating the air pressure, the extension length of the ejector pin 52 is precisely controlled, enabling fine adjustment of the local position of the chip 8 on the blue film 9.

In an embodiment, a sealing ring is added to the outer side of the ejector pin 52 to ensure a sealed connection between the ejector pin 52 and the inner wall of the correction through hole 54.

In an embodiment, the suction through hole 53 is a cylindrical through hole with a diameter of 1 mm, and the correction through hole 54 is a cylindrical through hole with a diameter of 1.5 mm.

In an embodiment, the error-correctable planar stretching expansion device further includes a rotation driver for driving the correction disk 51 to rotate horizontally.

In an embodiment, a stepper motor is selected as the rotation driver to drive the correction disk 51 to rotate in place. When the blue film 9 is placed on the correction disk 51, rotating the correction disk 51 can adjust the alignment direction of the chips 8 to be parallel to the stretching direction of the film expansion device. This solves the problem of difficulty in calculating the adjustment position when the arrangement direction of the chip 8 and the stretching direction are different.

In an embodiment, the film pressing frame 3 includes a first film pressing frame 31 and a second film pressing frame 32. The first film pressing frame 31 and the second film pressing frame 32 are arranged one above the other. The first film pressing frame 31 is engageable with the second film pressing frame 32. The engagement of the first film pressing frame 31 and the second film pressing frame 32 is used to clamp and fix the stretched blue film.

The height from the inner frame edge to the outer frame edge of the second film pressing frame 32 gradually decreases, forming an outward and downward inclined surface frame on the upper surface of the second film pressing frame 32. The inner frame edge of the second film pressing frame 32 is provided with a protruding platform, and the protruding platform 34 is flush with the upper surface of the correction disk 51. The film pressing frame 3 is square, and the side length of the film pressing frame 3 is less than the length L2 of the second film expansion mechanism.

The inclined surface frame facilitates the positioning and engagement of the first film pressing frame 31 and the second film pressing frame 32. In a specific embodiment, the protrusion height of the protruding platform 34 is 0.5 mm, ensuring the blue film 9 lies flat on the upper surface of the correction disk 51.

In an embodiment, the device further includes a plurality of pressing column heads 6. Each pressing column head 6 is provided with a through hole 61. A pushing block 62 is disposed within the through hole 61. The pushing block 62 is sealed against the inner wall of the through hole 61. One side of the through hole 61 is connected to a third air tube, which is externally connected to a first air pump. The side of the pushing block 62 away from the third air tube is provided with a locking arrow 7. The locking arrow 7 is used to lock the first film pressing frame 31 and the second film pressing frame 32 by locking through holes 33. The first film pressing frame 31 is provided with a plurality of first locking through holes 33A. The second film pressing frame 32 is provided with a plurality of second locking through holes 33B. The locking through holes 33 includes the first locking through holes 33A and the second locking through holes 33B. A plurality of first locking through holes 33A and a plurality of second locking through holes 33B are matched with corresponding through holes 61, respectively.

Under the control of the first air pump, the pushing block 62 can drive the locking arrow 7 to move downward to sequentially pass through the first locking through hole 33A of the first film pressing frame 31 and the second locking through hole 33B of the second film pressing frame 32.

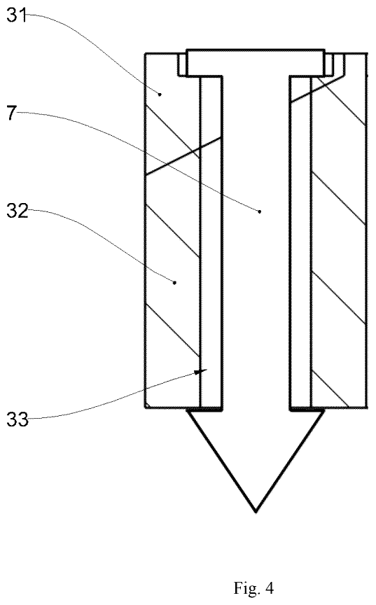

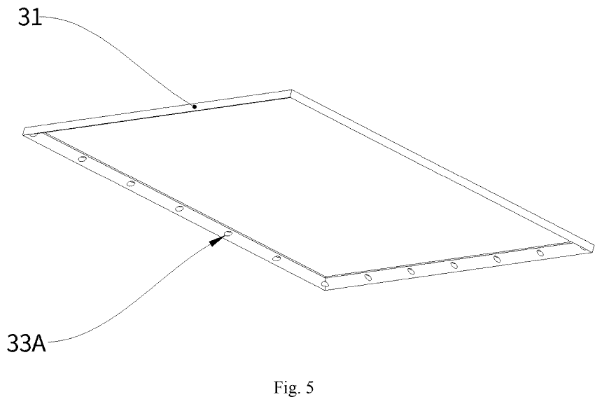

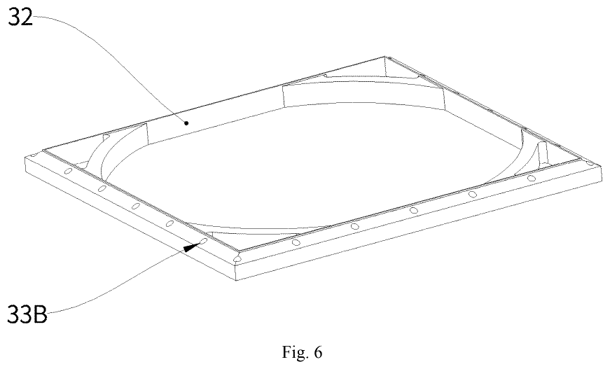

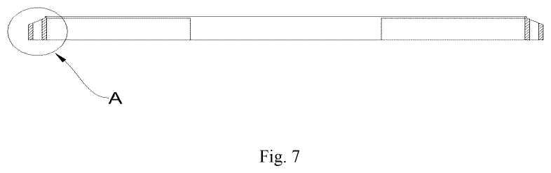

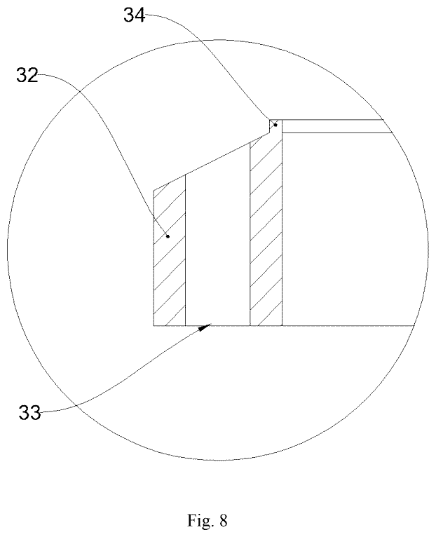

As shown in FIGS. 2 and 4-8, the first air pump supplies air to drive the pushing block 62 inside the through hole 61. The pushing block 62 then drives the locking arrow 7, which enters the locking through holes of the film pressing frames and penetrates the blue film 9 clamped between the film pressing frames 3, thereby locking the stretched blue film for easy transfer.

In an embodiment, before stretching the blue film 9, the first film pressing frame 31 is fixed beneath a plurality of pressing column heads 6. The pressing column heads 6 are connected to an external cylinder. During the stretching process, the blue film 9 is positioned between the first film pressing frame 31 and the second film pressing frame 32. When the stretching of the blue film 9 is completed, the cylinder drives the pressing column heads 6, which in turn pushes the first pressing frame 31 downward to engage with the second pressing frame 32 positioned beneath the blue film 9, thereby clamping the stretched blue film.

In an embodiment, the locking arrow 7 is made of polypropylene.

The use of polypropylene for the locking arrow provides a smooth surface, facilitating its movement within the passage. Additionally, the material offers both elasticity and high strength, meeting the operational requirements.

In an embodiment, the first film expansion mechanism includes a first roller assembly 11 and a first pressing block assembly 12. The first roller assembly 11 and the first pressing block assembly 12 are arranged oppositely and parallel to each other on both sides of the error correction mechanism 5 in the first direction. The first roller assembly 11 is used to stretch the blue film 9 in the second direction, and the first pressing block assembly 12 is used to fix the blue film 9 in the second direction.

The second film expansion mechanism includes a second roller assembly 21 and a second pressing block assembly 22. The second roller assembly 21 and the second pressing block assembly 22 are arranged oppositely and parallel to each other on both sides of the error correction mechanism 5 in the second direction. The second roller assembly 21 is used to stretch the blue film 9 in the first direction, and the second pressing block assembly 22 is used to secure the blue film 9 in the first direction.

The second direction is perpendicular to the first direction. The second roller assembly 21 and the second pressing block assembly 22 have the same length. The second roller assembly 21 and the second pressing block assembly 22 are disposed between the first roller assembly 11 and the first pressing block assembly 12, and the second roller assembly 21 is spaced apart from the first roller assembly 11 and the first pressing block assembly 12.

The first roller assembly 11 includes a first upper roller and a first lower roller. The first upper roller and the first lower roller are directly opposite each other and respectively located on two sides of the blue film 9 in its thickness direction.

The first pressing block assembly 12 includes a first upper pressing block and a first lower pressing block. The first upper pressing block and the first lower pressing block are directly opposite each other and disposed on two sides of the blue film 9 in the thickness direction, respectively.

The second roller assembly 21 includes a second upper roller 21A and a second lower roller 21B. The second upper roller 21A and the second lower roller 21B are directly opposite each other and disposed on two sides of the blue film 9 along its thickness direction, respectively.

The second pressing block assembly 22 includes a second upper pressing block 22A and a second lower pressing block 22B. The second upper pressing block 22A and the second lower pressing block 22B are directly opposite each other and disposed on two sides of the blue film 9 along its thickness direction, respectively.

With this structure, after the first roller assembly 11 and the first pressing block assembly 12 clamp the blue film 9, the first roller assembly 11 rolls to stretch the blue film 9 in the second direction. After the second roller assembly 21 and the second pressing block assembly 22 clamp the blue film 9, the second roller assembly 21 rolls to stretch the blue film 9 in the first direction.

In an embodiment, a first distance adjustment device is provided between the first upper roller and the first lower roller. The first distance adjustment device adjusts the distance between the first upper roller and the first lower roller. The distance between the first upper roller and the first lower roller is adjustable within a range of 0 to 10 mm. A second distance adjustment device 23 is provided between the second upper roller 21A and the second lower roller 21B. The second distance adjustment device 23 is used to adjust the distance between the second upper roller 21A and the second lower roller 21B. The spacing between the second upper roller 21A and the second lower roller 21B is adjustable within the range of 0 to 10 mm. The first upper roller, the first lower roller, the second upper roller 21A, and the second lower roller 21B are provided with fine knurling having a module of 0.2 mm. A third distance adjustment device is provided between the first upper pressing block and the first lower pressing block. The third distance adjustment device is used to adjust the distance between the first upper pressing block and the first lower pressing block. The spacing between the first upper pressing block and the first lower pressing block is adjustable within the range of 0 to 10 mm. A fourth distance adjustment device 24 is provided between the second upper pressing block 22A and the second lower pressing block 22B. The fourth distance adjustment device 24 is used to adjust the distance between the second upper pressing block 22A and the second lower pressing block 22B. The spacing between the second upper pressing block 22A and the second lower pressing block 22B is adjustable within the range of 0 to 10 mm.

The length of the first film expansion mechanism is L1, and the length of the second film expansion mechanism is L2. The side length of the maximum allowable square area of the blue film after film expansion is L3, where L3<L2<L1. A gap between the first film expansion mechanism and the second film expansion mechanism along the length direction of the second film expansion mechanism is d.

L3 is less than 80 mm. L2 is 20 mm longer than the side length of the film pressing frame 3. L1 is greater than the side length of the un-expanded blue film. d is greater than 30 mm.

The adjustable spacing of the roller assembly and the pressing block assembly facilitates quick clamping and releasing of the blue film, thereby enhancing chip processing efficiency.

In a specific embodiment, spring latches are used to quickly adjust the spacing between the roller assemblies and the pressing block assemblies. As a simple alternative, telescopic cylinders or motors may also be employed for spacing adjustment.

L1 is greater than the side length of the unstretched blue film, ensuring the entire blue film remains within the clamping range of the first film expansion mechanism for uniform overall stretching. L3 is designed to be less than 80 mm, as the stretched/expansion size is sufficient to meet the requirements for subsequent transfer process of the chips 8. During the second and third stretching/expansion stages, the edges of the blue film are fixed, while only the central region of the blue film undergoes stretching. L2 is 20 mm longer than the side length of the film pressing frame 3, and d is greater than 30 mm. This design maintains sufficient buffer zones between the edge and the central region of the blue film, ensuring uniform stretching in the central region and preventing irregular deformation caused by insufficient buffer areas.

In a specific embodiment, the film pressing frame 3 is made of 7075 aluminum alloy. The selection of 7075 aluminum alloy for the film pressing frame offers lightweight and high-strength properties, making it suitable for mechanisms involving high-frequency motion while also being easy to machine.

It should be noted that the first upper roller is not shown in the figures and can refer to the structure of the second upper roller 21A in FIG. 2. The first lower roller is not shown in the figures and can refer to the structure of the second lower roller 21B in FIG. 2. The first upper pressing block is not shown in the figures and can refer to the structure of the second upper pressing block 22A in FIG. 2. The first lower pressing block is not shown in the figures and can refer to the structure of the second lower pressing block 22B in FIG. 2. The first distance adjustment device is not shown in the figures and can refer to the structure of the second distance adjustment device 23 in FIG. 2. The third distance adjustment device is not shown in the figures and can refer to the structure of the fourth distance adjustment device 24 in FIG. 2.

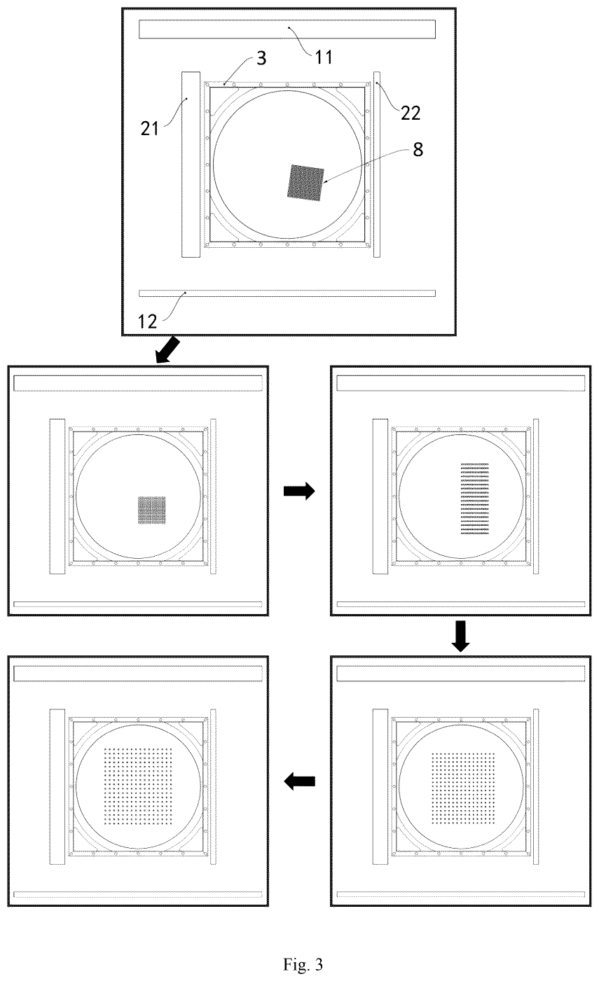

Referring to FIG. 3, an error-correctable planar stretching expansion method for chips by the error-correctable planar stretching expansion device described above includes the following steps.

### (A) Placing the Blue Film and Startup

The blue film 9 with chips is placed onto the correction disk 51, and the scanning camera 4 is activated to observe the spacing between the chips 8 on the blue film 9 in real time.

### (B) First Bidirectional Film Expansion

The first film expansion mechanism stretches the blue film 9 until the distance between any two adjacent chips 8 along the second direction reaches 96% of the target spacing (set spacing). The second film expansion mechanism stretches the blue film 9 until the distance between any two adjacent chips 8 along the first direction reaches 96% of the target spacing (set spacing). The target spacing represents the required distance between adjacent chips 8 for subsequent processing steps.

### (C) Error Identification

The scanning camera acquires the positions of all chips 8. It will be determined whether the chip spacing in certain regions is below 95% of the set spacing. If the chip spacing in a region is greater than or equal to 95% of the set spacing, mark that region as an adjusted area. If the chip spacing in a region is less than 95% of the set spacing, mark that region as an error region. One error region is selected, and it will be determined whether the error region is a convex polygon: if yes, proceed to the step (D); if not, the error region is a concave polygon. The concave polygon is divided into multiple convex polygons, then proceed to step (D). If the error region is already the smallest adjustable unit and cannot be further divided, proceed directly to step (D).

### (D) Error Correction

The ejector pin(s) in the correction disk corresponding to the error region are controlled to extend upward, thereby lifting, stretching, and expanding the blue film 9 within the error region.

### (E) Error Elimination Verification

The corrected error region is re-identified using the scanning camera. If the chip spacing within the corrected error region still does not fully reach 95% of the set spacing, and the corrected error region is not the minimum adjustable range, the process returns to step (C) for re-identification and division. If the corrected error region is the minimum adjustable range, the process returns to step (D) for repeat adjustment while accumulating the adjustment count for the corrected error region. When the cumulative adjustment count exceeds the preset maximum count, the adjustment step is abandoned, and the corrected error region is marked as an adjusted region. The process continues until all regions are marked as adjusted regions, then proceed to step (F).

### (F) Second Bidirectional Film Expansion

The first film expansion mechanism stretches the blue film 9 that has undergone error elimination verification. During this process, the scanning camera 4 monitors the spacing of chips 8 in the second direction in real time, and the stretching step is stopped when the average chip spacing equals the set spacing. The second film expansion mechanism then stretches the blue film 9 while the scanning camera 4 monitors the spacing in the second direction in real time, and stretching is completed when the average chip spacing reaches the set spacing.

This method utilizes the coordination of the scanning camera 4 and the ejector pins 52 to adjust the spacing of chips 8 in any arbitrary area of the blue film, thereby reducing spacing errors after stretching film and solving the problem in conventional stretching methods which cannot accurately adjust the spacing of the chips 8. Stretching the chips 8 on the blue film 9 to 96% of the target maximum spacing provides margin for local error adjustment. Exceeding 96% of the target maximum spacing would leave insufficient margin, and easily cause over-expansion of the blue film 9, while below 96% of the target maximum spacing would increase the margin, the large expansion would be required in subsequent stretching steps, thereby resulting in increased new errors.

In a specific embodiment, step (A) further includes adjusting the chip arrangement angle. By rotating the blue film via the correction disk to align the chip arrangement direction with the stretching direction, step (B) is then performed. During adjustment of the error region, negative pressure is applied to the suction through holes 53 outside the error region, while gas is introduced into the correction through holes 54 within the error area to cause the corresponding ejector pins 52 to protrude by 1 mm. Subsequently, both the suction through holes 53 and the correction through holes 54 return to atmospheric pressure to release the blue film. Due to the inherent delay in blue film deformation, a 15-second wait period is observed, and the area is then re-examined using the scanning camera 4. If the chip spacing still fails to exceed 95%, the adjustment process is repeated.

A Mini-LED chip film expansion apparatus utilizing the aforementioned error-correctable planar stretching film expansion device.

### Implementation Example

### Blue Film Positioning

The first film expansion mechanism and the second film expansion mechanism are separated vertically by a 10 mm gap. The blue film 9 to be expanded is placed on the correction disk 51 with the chips 8 facing upward. The chips 8 are positioned close to the first pressing block assembly 12 and the second pressing block assembly 22, without exceeding the boundary of the correction disk 51.

### Angle Adjustment

The scanning camera 4 detects the deflection angle of the central row of chips 8 as the overall deflection angle. Negative pressure is applied to all suction through holes 53 on the correction disk 5 to secure the blue film 9. The correction disk is then rotated by the corresponding angle to eliminate the overall angular deviation of the blue film 9. All the suction through holes 53 then return to atmospheric pressure to release the blue film 9. Finally, the correction disk is rotated back by the corresponding angle in the opposite direction to complete the reset procedure.

### First Bidirectional Film Expansion

The first film expansion mechanism clamps the blue film 9 vertically. The first roller assembly 11 rolls to stretch the blue film 9 along the second direction, while the scanning camera 4 monitors the spacing between adjacent chips 8 in the second direction in real time, with a target spacing of 300 μm. When the spacing between adjacent chips 8 in the second direction reaches 288 μm, the first roller assembly 11 stops rolling. Subsequently, the second film expansion mechanism clamps the blue film 9 vertically. The second roller assembly 21 rolls to stretch the blue film 9 along the first direction, while the scanning camera 4 monitors the spacing between adjacent chips 8 in the first direction in real time. The target spacing is set to 300 μm. When the spacing between adjacent chips 8 in the first direction reaches 288 μm, the second roller assembly 21 stops rolling.

### Error Correction

The scanning camera 4 acquires the positions of all chips 8, identifying several regions where the chip spacing falls below 285 μm. One such error region is selected for adjustment. If the error region is a convex polygon, negative pressure is applied to the suction through holes 53 outside the error region, while gas is introduced into the correction through holes 54 within the error region to cause the corresponding ejector pins 52 to protrude by 1 mm, resulting in slight expansion of the blue film in that region. If the error region is a concave polygon, the concave polygon is divided into multiple convex polygons, and then the above operation is performed. After the operation, the suction through holes 53 and the correction through holes 54 return to atmospheric pressure to release the blue film. After 15 seconds, the scanning camera 4 re-identifies the area. If the chip spacing still fails to reach 285 μm or above, the adjustment process is repeated. If the spacing aligns with the overall target range of 285-288 μm, the process moves to the next error region for adjustment. Finally, 99% of the chips 8 are adjusted to achieve the spacing within the target range of 285-288 μm.

### Second Bidirectional Film Expansion

The first roller assembly 11 rotates to stretch the blue film 9 outward. During this process, the scanning camera 4 monitors the spacing of chips 8 in the second direction in real time. When the average spacing of chips 8 reaches 300 μm, the first roller assembly 11 stops rotating. The second roller assembly 21 then rotates to stretch the blue film outward. During this process, the scanning camera 4 monitors the spacing of chips 8 in the first direction in real time. When the average spacing of chips 8 reaches 300 μm, the second roller assembly 21 stops rotating.

### Fixing Film Pressing Frame 3

All the pressing column heads 6 descend simultaneously, thereby moving the first film pressing frame 31 downward to tightly seal against the second film pressing frame 32. The first film pressing frame 31 and the second film pressing frame 32 clamp and secure the blue film 9. High-pressure gas is supplied to the through hole 61 of the pressing column head 6. The locking arrow 7 ejects and engages the locking through hole, locking the first film pressing frame 31 and the second film pressing frame 32 together. The scanning camera 4 scans the positions of all chips 8 on the blue film and stores the data.

### Film Expansion Completion

The first film expansion mechanism and the second film expansion mechanism are separated vertically to create a gap. The film pressing frame 3 is then removed, and any excess blue film is trimmed away with scissors.

Other components and operations according to the embodiments of the present disclosure are known to those of ordinary skill in the art and will not be described in detail herein.

As used herein, the terms “embodiment”, “example”, or similar language mean that the specific features, structures, materials or characteristics described in conjunction with such embodiments or examples are included in at least one embodiment/example of the present disclosure. In the disclosure, the description of the above terms does not necessarily refer to the same embodiment or example. Further, the specific features, structures, materials or characteristics described may be combined in a suitable manner in any one or more embodiments.

Described above are merely preferred embodiments of the disclosure, which are not intended to limit the disclosure. It should be understood that any modifications and replacements made by those skilled in the art without departing from the spirit of the disclosure should fall within the scope of the disclosure defined by the appended claims.

What is claimed is:

1. An error-correctable planar stretching expansion device for chips, comprising:
a first film expansion mechanism;
a second film expansion mechanism;
a film pressing frame;
a scanning camera; and
an error correction mechanism;
wherein an expansion direction of the first film expansion mechanism is perpendicular to an expansion direction of the second film expansion mechanism;
the film pressing frame is configured to secure a blue film carrying the chips;
the error correction mechanism is configured to perform a localized expansion of the blue film;
the scanning camera is configured to detect positions of the chips on the blue film;
the error correction mechanism comprises a correction disk, a plurality of ejector pins, and a drive mechanism;
the correction disk is provided with a plurality of suction through holes and a plurality of correction through holes; the plurality of suction through holes are uniformly distributed in the correction disk; the plurality of suction through holes are externally connected to an air extraction mechanism; the plurality of suction through holes are configured to absorb and fix the blue film to an upper surface of the correction disk under an action of the air extraction mechanism; and the plurality of correction through holes are uniformly distributed between the plurality of suction through holes; and
the plurality of ejector pins are movably arranged in the plurality of correction through holes in a vertical direction, with one ejector pin corresponding to one correction through hole; vertical movements of the plurality of ejector pins are independent of each other; driven by the drive mechanism, at least one ejector pin moves upward to protrude the upper surface of the correction disk; and the at least one ejector pin protruding upwardly is configured to locally expand the blue film.

2. The error-correctable planar stretching expansion device of claim 1, wherein each suction through hole is provided with a porous ceramic which flushes with the upper surface of the correction disk; the plurality of suction through holes are externally connected to the air extraction mechanism via a flexible tube; and the air extraction mechanism is a negative pressure pump; and
each ejector pin is arranged at an end of a corresponding correction through hole proximate to the upper surface of the correction disk; the each ejector pin has a cylindrical structure with a hemispherical upper end; an outer wall of the each ejector pin is sealed against an inner wall of the corresponding correction through hole; when not moving upward, an upper end of the each ejector pin does not protrude beyond the upper surface of the correction disk; and an other end of the corresponding correction through hole is connected to an air tube which is connected to the drive mechanism, wherein the drive mechanism is an external air pressure adjustment system.

3. The error-correctable planar stretching expansion device of claim 2, wherein the each suction through hole is a cylindrical through hole with a diameter of 1 mm, and each correction through hole is a cylindrical through hole with a diameter of 1.5 mm.

4. The error-correctable planar stretching expansion device of claim 1, further comprising a rotation driver configured to drive the correction disk to rotate in a horizontal direction.

5. The error-correctable planar stretching expansion device of claim 1, wherein the film pressing frame comprises a first film pressing frame and a second film pressing frame; the first film pressing frame and the second film pressing frame are vertically stacked; and the first film pressing frame is engageable with the second film pressing frame for clamping and fixing a stretched blue film; and
a height of the second film pressing frame gradually decreases from an inner frame edge of the second film pressing frame to an outer frame edge of the second film pressing frame, forming an outward and downward inclined surface frame on an upper surface of the second film pressing frame; the inner frame edge of the second film pressing frame is provided with a protruding platform, which is flushed with the upper surface of the correction disk; and the film pressing frame is square, and a side length of the film pressing frame is less than a length L2 of the second film expansion mechanism.

6. The error-correctable planar stretching expansion device of claim 5, further comprising a plurality of pressing column heads;
each pressing column head is provided with a through hole; a pushing block is disposed within the through hole and sealed against an inner wall of the through hole; a side of the through hole is connected to a third air tube, and the third air tube is externally connected to a first air pump; a side of the pushing block away from the third air tube is provided with a locking arrow, which is configured to lock the first film pressing frame and the second film pressing frame; the first film pressing frame is provided with a plurality of first locking through holes; the second film pressing frame is provided with a plurality of second locking through holes; and the plurality of first locking through holes and the plurality of second locking through holes are matched with corresponding through holes, respectively; and
under an action of the first air pump, the pushing block drives the locking arrow to move downward sequentially through each first locking through hole and each second locking through hole.

7. The error-correctable planar stretching expansion device of claim 1, wherein the first film expansion mechanism comprises a first roller assembly and a first pressing block assembly; the first roller assembly and the first pressing block assembly are arranged oppositely and parallel to each other on both sides of the error correction mechanism in a first direction; the first roller assembly is configured to stretch a blue film in a second direction; and the first pressing block assembly is configured to secure the blue film in the second direction;
the second film expansion mechanism comprises a second roller assembly and a second pressing block assembly; the second roller assembly and the second pressing block assembly are arranged oppositely and parallel to each other on both sides of the error correction mechanism in the second direction; the second roller assembly is configured to stretch a blue film in the first direction; and the second pressing block assembly is configured to secure the blue film in the first direction;
the first direction is perpendicular to the second direction; the second roller assembly and the second pressing block assembly have a same length; the second roller assembly and the second pressing block assembly are disposed between the first roller assembly and the first pressing block assembly; and the second roller assembly is spaced apart from the first roller assembly and the first pressing block assembly;
the first roller assembly comprises a first upper roller and a first lower roller; the first upper roller and the first lower roller are directly opposite each other; and the first upper roller and the first lower roller are respectively disposed on two sides of the blue film in a thickness direction thereof;
the first pressing block assembly comprises a first upper pressing block and a first lower pressing block; the first upper pressing block and the first lower pressing block are directly opposite each other; and the first upper pressing block and the first lower pressing block are respectively disposed on the two sides of the blue film in the thickness direction thereof;
the second roller assembly comprises a second upper roller and a second lower roller; the second upper roller and the second lower roller are directly opposite each other; and the second upper roller and the second lower roller are respectively disposed on the two sides of the blue film in the thickness direction thereof; and
the second pressing block assembly comprises a second upper pressing block and a second lower pressing block; the second upper pressing block and the second lower pressing block are directly opposite each other; and the second upper pressing block and the second lower pressing block are respectively disposed on the two sides of the blue film in the thickness direction thereof.

8. The error-correctable planar stretching expansion device of claim 7, wherein a first distance adjustment device is provided between the first upper roller and the first lower roller and configured to adjust a distance between the first upper roller and the first lower roller; and the distance between the first upper roller and the first lower roller is adjustable within a range of 0 to 10 mm;
a second distance adjustment device is provided between the second upper roller and the second lower roller and configured to adjust a distance between the second upper roller and the second lower roller; and the distance between the second upper roller and the second lower roller is adjustable within a range of 0 to 10 mm;
the first upper roller, the first lower roller, the second upper roller, and the second lower roller are each provided with a knurling having a module of 0.2 mm;
a third distance adjustment device is provided between the first upper pressing block and the first lower pressing block and configured to adjust a distance between the first upper pressing block and the first lower pressing block; and the distance between the first upper pressing block and the first lower pressing block is adjustable within a range of 0 to 10 mm;
a fourth distance adjustment device is provided between the second upper pressing block and the second lower pressing block and configured to adjust a distance between the second upper pressing block and the second lower pressing block; and the distance between the second upper pressing block and the second lower pressing block is adjustable within a range of 0 to 10 mm;
a length of the first film expansion mechanism is L1; the length of the second film expansion mechanism is L2; a side length of a maximum allowable square area of a central region of the blue film after expansion is L3, wherein L3<L2<L1; and a gap between the first film expansion mechanism and the second film expansion mechanism along a length direction of the second film expansion mechanism is d; and
L3 is less than 80 mm; L2 is 20 mm longer than a side length of the film pressing frame; L1 is greater than a side length of the blue film before expansion; and d is greater than 30 mm.

9. An error-correctable planar stretching expansion method by the error-correctable planar stretching expansion device of claim 1, comprising:
(A) placing the blue film carrying the chips onto the correction disk, and observing a spacing between the chips on the blue film in real time by the scanning camera;
(B) performing a first bidirectional film expansion through steps of:
stretching, by the first film expansion mechanism, the blue film until a spacing between two adjacent chips along the second direction reaches 96% of a set spacing; and
stretching, by the second film expansion mechanism, the blue film until a spacing between two adjacent chips along the first direction reaches 96% of the set spacing, wherein the set spacing is a required spacing between adjacent chips for subsequent processing;
(C) performing error identification through steps of:
acquiring positions of the chips via the scanning camera;
determining whether a chip spacing in certain regions is below 95% of the set spacing:
if a chip spacing in a region is greater than or equal to 95% of the set spacing, marking the region as an adjusted region; and
if the chip spacing in a region is less than 95% of the set spacing, marking the region as an error region; selecting one error region and determining whether the one error region is a convex polygon: if yes, proceeding to a step (D); if no, the one error region is a concave polygon, dividing the concave polygon into a plurality of convex polygons and proceeding to the step (D); if the one error region is a smallest adjustable unit and cannot be divided, proceeding directly to the step (D);
(D) performing error correction through steps of:
controlling an ejector pin on the correction disk corresponding to the error region to extend upward, thereby lifting and stretching the blue film in the error region;
(E) performing error elimination verification through steps of:
re-identifying a corrected error region by the scanning camera;
if a chip spacing within the corrected error region still fails to all reach 95% of the set spacing, and the corrected error region is not the smallest adjustable unit, returning to the step (C) for re-identification and division; and
if the corrected error region is within the minimum adjustable unit, returning to the step (D) for repeat adjustment; accumulating a number of adjustments for the corrected error region, when the number of adjustments exceeds a preset maximum number of adjustments, abandoning adjustment of the corrected error region and simultaneously marking the corrected error region as an adjusted region; until all regions are marked as adjusted regions, proceeding to a step (F);
(F) performing a second bidirectional film expansion through steps of:
stretching, by the first film expansion mechanism, the blue film after the error elimination verification, wherein the scanning camera observes chip spacings in the second direction in real time, when an average chip spacing equals to the set spacing, and stopping stretching steps; and
stretching, by the second film expansion mechanism, the blue film; wherein the scanning camera observes chip spacings in the first direction in real time, when an average chip spacing in the first direction equals the set spacing, and completing stretching.

10. A Mini-LED chip film expansion apparatus, comprising the error-correctable planar stretching expansion device of claim 1.
